(19) United States
(12) Patent Application Publication
(10) Pub. No.: US 2025/0359411 A1
(43) Pub. Date: Nov. 20, 2025

(54) DISPLAY PANEL AND METHOD FOR MANUFACTURING SAME, AND DISPLAY DEVICE

(71) Applicants: Hefei BOE Ruisheng Technology Co., Ltd., Hefei, Anhui (CN); BOE Technology Group Co., Ltd., Beijing (CN)

(72) Inventors: Jie WANG, Beijing (CN); Xintao WU, Beijing (CN); Jiawei XU, Beijing (CN); Zouming XU, Beijing (CN); Tingwei HAN, Beijing (CN); Ningyu LUO, Beijing (CN); Wenzhuo TANG, Beijing (CN)

(73) Assignees: Hefei BOE Ruisheng Technology Co., Ltd., Hefei, Anhui (CN); BOE Technology Group Co., Ltd., Beijing (CN)

(21) Appl. No.: 18/881,743

(22) PCT Filed: May 15, 2024
(86) PCT No.: PCT/CN2024/093295

§ 371 Date: Jan. 7, 2025

(30) Foreign Application Priority Data
Jun. 29, 2023 (CN) 202310789282.7

(51) Int. Cl. H10H 29/49; H10H 29/01

(52) U.S. Cl. CPC H10H 29/49; H10H 29/012

(57) ABSTRACT

Provided is a display panel. The display panel includes: a substrate having a first surface and a second surface opposite to each other and a plurality of side surfaces connecting the first surface and the second surface, wherein the first surface includes a display region and a peripheral region surrounding the display region; and a first surface wire disposed in the display region of the first surface, an electrode structure disposed in the peripheral region of the first surface, and a side wire disposed on at least one side surface of the plurality of side surfaces; wherein one end of the side wire is electrically connected to the electrode structure, and another end of the side wire extends through the first surface and the at least one side surface in sequence to the second surface, and the electrode structure is further electrically connected to the first surface wire.

### CROSS-REFERENCE TO RELATED APPLICATIONS

The present disclosure is a U.S. national stage of international application No. PCT/CN2024/093295, filed on May 15, 2024, which claims priority to Chinese patent application No. 202310789282.7, filed on Jun. 29, 2023, and entitled “DISPLAY PANEL AND METHOD FOR MANUFACTURING SAME, AND DISPLAY DEVICE”, the entire contents of each are incorporated herein by reference.

### TECHNICAL FIELD

The present disclosure relates to the field of display technology and more particularly to a display panel and a method for manufacturing the same, and a display device.

### BACKGROUND

Because of the advantages of self-illumination, high luminance, small volume and the like, mini light-emitting diodes (mini LEDs) have gradually become the mainstream of the market and are applicable to two scenarios of direct display or backlight display.

### SUMMARY

A display panel and a method for manufacturing the same, and a display device are provided. The technical solutions are as follows.

In some embodiments of the present disclosure, a display panel is provided. The display panel includes:
a substrate having a first surface and a second surface opposite to each other and a plurality of side surfaces connecting the first surface and the second surface, wherein the first surface includes a display region and a peripheral region surrounding the display region; and
a first surface wire disposed in the display region of the first surface, an electrode structure disposed in the peripheral region of the first surface, and a side wire disposed on at least one side surface of the plurality of side surfaces;
wherein one end of the side wire is electrically connected to the electrode structure, and the other end of the side wire extends through the first surface and the at least one side surface in sequence to the second surface, and the electrode structure is further electrically connected to the first surface wire; and
wherein the electrode structure includes: a buffer layer, at least one layer of conductive pattern, and at least one passivation layer disposed on a side, away from the substrate, of each layer of conductive pattern, which are disposed on a side of the substrate and sequentially laminated along a direction away from the substrate, wherein a first angle between any passivation layer of the at least one passivation layer and a bearing surface of the substrate is less than or equal to a second angle between a conductive pattern of the at least one layer of conductive pattern which is close to the substrate and the bearing surface of the substrate.

In some embodiments, the first angle and the second angle are equal and are both 0 degree; and the electrode structure includes:
a first conductive pattern, a first passivation layer, and a second passivation layer which are sequentially laminated along the direction away from the substrate;
a through hole penetrating through the first passivation layer and the second passivation layer and exposing the first conductive pattern; and
a protective layer disposed in the through hole and covering the first conductive pattern.

In some embodiments, the first angle is less than the second angle, and the first angle and the second angle are both greater than 0 degree and less than 90 degrees; and the electrode structure includes:
a first conductive pattern, a first passivation layer, a second conductive pattern, and a second passivation layer which are sequentially laminated along the direction away from the substrate, wherein an orthographic projection of the first conductive pattern on the substrate is within an orthographic projection of the second conductive pattern on the substrate;
a through hole penetrating through the second passivation layer and exposing the second conductive pattern;
a protective layer disposed in the through hole and covering the second conductive pattern;
a connection hole penetrating through the first passivation layer and exposing the first conductive pattern, wherein the second conductive pattern is connected to the first conductive pattern through the connection hole, and the connection hole is farther from the at least one side surface than the through hole is; and
a spacer layer disposed between the first conductive pattern and the first passivation layer, wherein an orthographic projection of the spacer layer on the substrate is within an orthographic projection of the first passivation layer on the substrate, the spacer layer covers a side surface of the first conductive pattern which is in contact with the buffer layer and a top surface of the first conductive pattern which is away from the buffer layer, and a thickness of the spacer layer is greater than a thickness of any other film layer in the electrode structure.

In some embodiments, a third angle between the spacer layer and the bearing surface of the substrate is less than the second angle and is equal to the first angle; and

first angles between various passivation layers and the bearing surface of the substrate are equal, and a fourth angle between the second conductive pattern and the bearing surface of the substrate is equal to the first angle.

In some embodiments, the thickness of the spacer layer is greater than 3 μm.

In some embodiments, a material of the spacer layer includes a resin material.

In some embodiments, the electrode structure further includes:
a third passivation layer disposed between the first conductive pattern and the spacer layer, wherein the connection hole further penetrates through the third passivation layer to expose the first conductive pattern.

In some embodiments, the first surface wire includes: a first wire layer and a second wire layer which are sequentially laminated along the direction away from the substrate; wherein
one layer of first conductive pattern in the electrode structure is disposed in a same layer as the first wire layer; or
in two layers of conductive patterns including the first conductive pattern and a second conductive pattern which are sequentially laminated in the electrode structure, the first conductive pattern is disposed in a same layer as the first wire layer, and the second conductive pattern is disposed in a same layer as the second wire layer.

In some embodiments, a thickness of the protective layer in the electrode structure is greater than a depth of the through hole, and a material of the protective layer includes a metal material.

In some embodiments, the material of the protective layer includes: nickel, gold, and a combination thereof.

In some embodiments, the at least one layer of conductive pattern in the electrode structure includes: a plurality of layers of sub-conductive patterns which are sequentially laminated along the direction away from the substrate.

In some embodiments, the at least one layer of conductive pattern in the electrode structure includes: three layers of sub-conductive patterns which are sequentially laminated along the direction away from the substrate; wherein
materials of the three layers of sub-conductive patterns sequentially include molybdenum, copper, and molybdenum, or sequentially include molybdenum and niobium, copper, and molybdenum and niobium.

In some embodiments, the at least one layer of conductive pattern includes: a conductive pattern, close to the side of the substrate, of the at least one layer of conductive pattern.

In some embodiments, a thickness of at least one passivation layer in the electrode structure is greater than 2000 Å and less than or equal to 4000 Å.

In some embodiments, the at least one passivation layer includes a passivation layer, away from the side of the substrate, of the at least one passivation layer.

In some embodiments of the present disclosure, a method for manufacturing a display panel is provided. The method is applicable for manufacturing the display panel as described in the above embodiments. The method includes:
providing a substrate, wherein the substrate has a first surface and a second surface opposite to each other and a plurality of side surfaces connecting the first surface and the second surface, the first surface includes a display region and a peripheral region surrounding the display region;
forming a first surface wire in the display region of the first surface and forming an electrode structure in the peripheral region of the first surface, wherein the electrode structure is electrically connected to the first surface wire; and
forming a side wire on at least one side surface of the plurality of side surfaces, wherein one end of the side wire is electrically connected to the electrode structure, and the other end of the side wire extends through the first surface and the at least one side surface in sequence to the second surface;
wherein the formed electrode structure includes: a buffer layer, at least one layer of conductive pattern, and at least one passivation layer disposed on a side, away from the substrate, of each layer of conductive pattern, which are disposed on a side of the substrate and sequentially laminated along a direction away from the substrate, wherein a first angle between any passivation layer of the at least one passivation layer and a bearing surface of the substrate is less than or equal to a second angle between a conductive pattern of the at least one layer of conductive pattern which is close to the substrate and the bearing surface of the substrate.

In some embodiments, the first angle and the second angle are equal and are both 0 degree; and forming the electrode structure in the peripheral region of the first surface includes:
forming a first conductive pattern, a first passivation layer, and a second passivation layer which are sequentially laminated along the direction away from the substrate on the side of the substrate;
forming a through hole penetrating through the first passivation layer and the second passivation layer and exposing the first conductive pattern; and
forming a protective layer covering the first conductive pattern in the through hole.

In some embodiments, the first angle is less than the second angle, and the first angle and the second angle are both greater than 0 degree and less than 90 degrees; and forming the electrode structure in the peripheral region of the first surface includes:
forming a first conductive pattern, a first passivation layer, a second conductive pattern, and a second passivation layer which are sequentially laminated along the direction away from the substrate on the side of the substrate, wherein an orthographic projection of the first conductive pattern on the substrate is within an orthographic projection of the second conductive pattern on the substrate;
forming a through hole penetrating through the second passivation layer and exposing the second conductive pattern;
forming a protective layer covering the second conductive pattern in the through hole;
forming a connection hole penetrating through the first passivation layer and exposing the first conductive pattern, wherein the connection hole is farther from the at least one side surface than the through hole is;
connecting the second conductive pattern to the first conductive pattern through the connection hole; and
forming a spacer layer between the first conductive pattern and the first passivation layer, wherein an orthographic projection of the spacer layer on the substrate is within an orthographic projection of the first passivation layer on the substrate, the spacer layer covers a side surface of the first conductive pattern which is in contact with the buffer layer and a top surface of the first conductive pattern which is away from the buffer layer, and a thickness of the spacer layer is greater than a thickness of any other film layer in the electrode structure.

In some embodiments, forming the first surface wire in the display region of the first surface includes: forming a film using a conductive material in a corresponding region and forming the first surface wire by a yellow light process in the display region of the first surface;

forming the side wire on the at least one side surface of the plurality of side surfaces includes: forming a film using a conductive material in a corresponding region and forming the side wire by a laser etching process on the at least one side surface of the plurality of side surfaces.

In some embodiments of the present disclosure, a display device is provided. The display device includes: a power supply assembly, and the display panel as described in the above embodiments.

The power supply assembly is coupled to the display panel and is configured to supply power to the display panel.

### BRIEF DESCRIPTION OF DRAWINGS

For a clearer description of the technical solutions in the embodiments of the present disclosure, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic diagram of a front structure of a display panel according to some embodiments of the present disclosure;

FIG. 2 is a sectional schematic diagram of a display panel on the basis of the structure shown in FIG. 1;

FIG. 3 is a sectional schematic diagram of another display panel on the basis of the structure shown in FIG. 1;

FIG. 4 is a schematic structural diagram of film layers of an electrode structure in a display panel according to some embodiments of the present disclosure;

FIG. 5 is a schematic structural diagram of film layers of an electrode structure in a display panel in the related art;

FIG. 6 is a top view of a display panel on the basis of the structure shown in FIG. 4;

FIG. 7 is a sectional schematic diagram of another display panel on the basis of the structure shown in FIG. 6;

FIG. 8 is a schematic structural diagram of a pixel in a display panel according to some embodiments of the present disclosure;

FIG. 9 is a schematic diagram of an SEM slice of a display panel according to some embodiments of the present disclosure;

FIG. 10 is a schematic diagram of a process for forming a conductive pattern according to some embodiments of the present disclosure;

FIG. 11 is a schematic structural diagram of film layers of an electrode structure in another display panel according to some embodiments of the present disclosure;

FIG. 12 is a schematic structural diagram of film layers of an electrode structure in another display panel according to some embodiments of the present disclosure;

FIG. 13 is a schematic structural diagram of film layers of a first wire layer in a display panel according to some embodiments of the present disclosure;

FIG. 14 is a schematic diagram of an SEM slice of another display panel according to some embodiments of the present disclosure;

FIG. 15 is a schematic diagram of an SEM slice of another display panel according to some embodiments of the present disclosure;

FIG. 16 is a flowchart of a method of manufacturing a display panel according to some embodiments of the present disclosure; and

FIG. 17 is a schematic structural diagram of a display device according to some embodiments of the present disclosure.

### DETAILED DESCRIPTION

In order to make the objects, technical solutions and advantages of the present disclosure clearer, the embodiments of the present disclosure will be described in further detail below in conjunction with the accompanying drawings.

In the related art, a large-size display product including a mini LED generally includes multiple spliced display panels. In consideration of the influence of the splicing seam on display, currently, a driver chip is provided on the back surface of the display panel, a light-emitting element and an electrode structure are provided on the front surface of the display panel, and side wires are provided on a side surface of the display panel. One end of the side wire is electrically connected to the light-emitting element through the electrode structure, and the other end of the side wire extends through the front surface and the side surface in sequence to the back surface and is electrically connected to the driver chip. In this way, the driver chip is indirectly connected to the light-emitting element to drive the light-emitting element to emit light. Moreover, the current electrode structure generally includes a buffer layer, a conductive pattern, and a passivation layer which are sequentially laminated.

However, due to the influence of the manufacturing process, adjacent film layers in the current electrode structure easily peel, resulting in a poor yield of the display product.

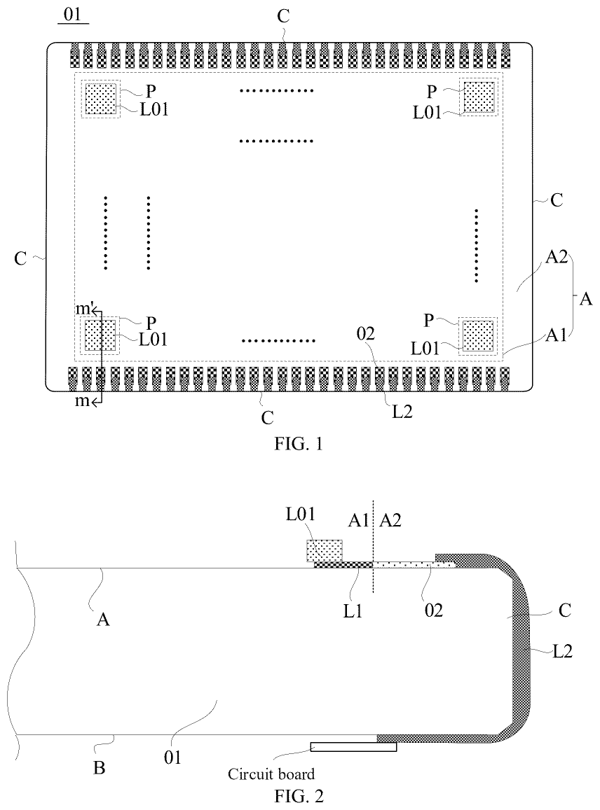

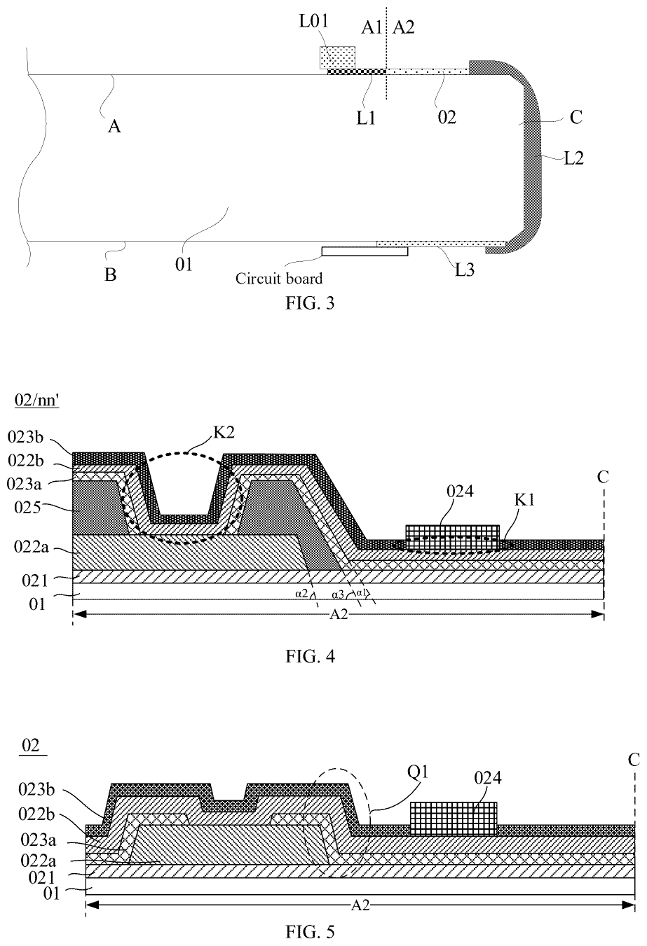

FIG. 1 is a schematic structural diagram of a display panel according to some embodiments of the present disclosure. FIG. 2 is a sectional diagram of a display panel along the mm′ direction on the basis of FIG. 1, and FIG. 3 is a sectional diagram of another display panel along the mm′ direction on the basis of FIG. 1. As can be seen from FIG. 1 to FIG. 3, the display panel provided in the embodiments of the present disclosure includes a substrate 01.

The substrate 01 has a first surface A and a second surface B opposite to each other and a plurality of side surfaces C connecting the first surface A and the second surface B. The first surface A includes a display region A1 and a peripheral region A2 which is closer to the side surfaces C than the display region A1 is. Exemplarily, the substrate 01 shown in FIG. 1 has four side surfaces C.

In some embodiments, the peripheral region A2 surrounds the display region A1 which is rectangular and surrounds the display region A1, as shown in FIG. 1. Alternatively, in some embodiments, the peripheral region A2 partially surrounds the display region A1, for example, the peripheral region A2 is at the lower side of the rectangular display region A1, as shown in FIG. 1, which is not limited in the embodiments of the present disclosure. Additionally, the display region A1 and the peripheral region A2 are both rectangular, as shown in FIG. 1. Alternatively, in some embodiments, the display region A1 and the peripheral region A2 are both circular or elliptic, which is not limited in the embodiments of the present disclosure. Furthermore, the contours of the shapes of the peripheral region A2 and the display region A1 are regular shapes. Alternatively, in some embodiments, the shapes of the peripheral region A2 and the display region A1 are irregular shapes. In order to ensure the display effect, the area of the display region A1 is generally greater than the area of the peripheral region A2.

As can be further seen from FIG. 1 to FIG. 3, the display panel provided in the embodiments of the present disclosure further includes a first surface wire L1 disposed in the display region A1 of the first surface A, an electrode structure 02 disposed in the peripheral region A2 of the first surface A, and a side wire L2 disposed on at least one side surface C of the plurality of side surfaces C. Exemplarily, in the display panel shown in FIG. 1, the at least one side surface C is two opposite side surfaces of four side surfaces. One end of the side wire L2 is electrically connected to the electrode structure 02, and the other end of the side wire L2 extends through the first surface A and the at least one side surface C in sequence to the second surface B. The electrode structure 02 is further electrically connected to the first surface wire L1.

In some embodiments, as can be further seen from FIG. 1 to FIG. 3, the display panel provided in the embodiments of the present disclosure further includes a plurality of light-emitting elements L01 disposed in the display region A1 and an external circuit board disposed on the second surface B. The first surface wire L1 is further electrically connected to the light-emitting elements L01, and the side wire L2 is further electrically connected to the external circuit board at the location where the side wire L2 reaches the second surface B. In this way, the purpose of connecting the external circuit board to the light-emitting elements L01 is achieved, and the external circuit board can reliably drive the light-emitting elements L01 to emit light.

In some embodiments, as shown in FIG. 2, the portion of the side wire L2 which is disposed on the second surface B has a fan-out line structure, and the free end of the side wire L2 which extends through the first surface A and the at least one side surface C to the second surface B is electrically connected to a gold finger structure of the external circuit board, thereby achieving the purpose of connecting the external circuit board to the light-emitting elements L01 through the side wire L2 and the first surface wire L1 in sequence.

Alternatively, in some other embodiments, as shown in FIG. 3, the display panel provided in the embodiments of the present disclosure further includes a second surface wire L3 disposed on the second surface B. The second surface wire L3 has a fan-out line structure, one end of the second surface wire L3 which has the fan-out line structure is electrically connected to the gold finger structure of the external circuit board, and the other end of the second surface wire L3 is electrically connected to the side wire L2, thereby achieving the purpose of connecting the external circuit board to the light-emitting elements L01 through the second surface wire L3, the side wire L2, and the first surface wire L1 in sequence. That is, in some others embodiments, the free end of the side wire L2 which extends through the first surface A and the at least one side surface C to the second surface B is further electrically connected to the second surface wire L3 on the second surface B and is indirectly electrically connect to the external circuit board through the second surface wire L3.

In some embodiments, the display panel further includes a plurality of first surface wires L1, a plurality of electrode structures 02, a plurality of side wires L2, and a plurality of second surface wires L3. The plurality of first surface wires L1 and the plurality of electrode structures 02 are connected in one-to-one correspondence, that is, each first surface wire L1 is connected to one electrode structure 02, and the various first surface wires L1 are connected to different electrode structures 02. The plurality of side wires L2 are connected in one-to-one correspondence to the plurality of electrode structures 02 and are connected in one-to-one correspondence to the plurality of second surface wires L3, that is, each side wire L2 is connected to one electrode structure 02 and one second surface wire L3, and the various side wires L2 are connected to different electrode structures 02 and are connected to different second surface wires L3.

In some embodiments, in conjunction with FIG. 2, in the embodiments of the present disclosure, the first surface wire L1 and the electrode structure 02 to which the first surface wire L1 is electrically connected is of an integral structure, and the second surface wire L3 and the side wire L2 to which the second surface wire L3 is electrically connected is of an integral structure. In this way, the process can be simplified, and the costs can be saved.

In some embodiments, the light-emitting element L01 includes, but is not limited to, a mini LED, an organic light-emitting diode (OLED), and a micro light-emitting diode (micro LED). The size of the mini LED is between the size of the OLED and the size of the micro LED, and is about 100 μm to 200 μm. The embodiments of the present disclosure are described by taking an example where the light-emitting element L01 is a mini LED.

It should be noted that on the premise that the light-emitting element L01 disposed in the display region A1 of the first surface A emits light, it is known that the first surface A is a light-emitting surface of the display panel, and accordingly, the second surface B opposite to the first surface A is a backlight surface of the display panel. In the embodiments of the present disclosure, the first surface A, which is the light-emitting surface, may also be referred to as a front surface, and the second surface B, which is the backlight surface, may also referred to as a back surface. Accordingly, the first surface wire L1 disposed on the first surface A may also be referred to as a front surface wire, and the second surface wire L3 disposed on the second surface B may be referred to as a back surface wire. As can be known from the above embodiments, in the embodiments of the present disclosure, the bonding region of the light-emitting element L01 and the external circuit board is transferred to the back surface of the display panel, and the bonding connection between the light-emitting element L01 and the external circuit board is achieved by means of the front surface wires, side surface wires, and the back surface wires. It is usually applied in the scenario where all four sides of the direct display product can be spliced together, to avoid the splicing seam from affecting the display uniformity of the product.

Additionally, in some embodiments, the front surface wire is manufactured by a yellow light process, and the side wire and the back surface wire are manufactured by a laser etching process. The process in this implementation may be referred to as a single-sided back plate (BP) process. Alternatively, in some embodiments, the front surface wire and the back surface wire are both manufactured by the yellow light process, and only the side wire is manufactured by the laser etching process. The process in this implementation may be referred to as a double-sided BP process. The process for manufacturing the panel is not limited in the embodiments of the present disclosure.

On the basis of the structures shown in FIG. 1 to FIG. 3, as can be seen from FIG. 4 which is a diagram of a film layer structure, in the display panel provided in the embodiments of the present disclosure, the electrode structure 02 disposed in the peripheral region A2 includes a buffer layer 021, at least one layer of conductive pattern 022, and at least one passivation layer 023 disposed on a side of each layer of conductive pattern 022, which are disposed on a side of the substrate 01 and are sequentially laminated along a direction away from the substrate 01.

A first angle α1 between any one of the at least one passivation layer 023 and a bearing surface of the substrate 01 is less than or equal to (i.e., not greater than) a second angle α2 between the conductive pattern 022 of the at least one layer of conductive pattern 022 which is close to the substrate 01 and the bearing surface of the substrate 01. That is, in the embodiments of the present disclosure, even if the conductive pattern 022 close to the substrate 01 has a larger thickness, a steeper slope, and a larger angle with the substate 01 due to the influence of the manufacturing process and the material of the film layer, other film layers disposed on the side, away from the substate 01, of the conductive pattern 022 with a steeper slope can be set to have a gentler slope and have a smaller angle with the substate 01 to avoid peeling between the film layers.

In some embodiments, the electrode structure 02 further includes a wire protection layer covering the side wire L2 and disposed on at least one side surface C, and the wire protection layer protects the side wire L2 and plays a role of electrical insulation and water and oxygen corrosion protection to protect the side wire L2 from external damage, thereby preventing the side wire L2 from peeling, breaking or oxidization. In some embodiments, the wire protection layer is, for example, a protective adhesive layer or an ink layer.

In summary, the embodiments of the present disclosure provide a display panel. In the display panel, the side wire is electrically connected to the first surface wire through an electrode structure and extends through the first surface and the side surface in sequence to the second surface. The electrode structure includes at least one layer of conductive pattern and at least one passivation layer disposed on a side, away from the substate, of each layer of conductive pattern, which are sequentially laminated along the direction away from the substrate. The angle between any passivation layer and the bearing surface of the substrate is less than or equal to the second angle between the conductive pattern close to the substrate and the bearing surface of the substrate, which can prevent the angle from being too large due to the influence of the manufacturing process, thereby preventing the film layers from climbing and peeling. Therefore, a better yield of the product can be ensured.

In an optional implementation, the first angle α1 between any passivation layer 023 and the bearing surface of the substrate 01 is less than the second angle 2 between the conductive pattern 022 close to the substrate 01 and the bearing surface of the substrate 01, and the first angle α1 and the second angle α2 are greater than 0 degree and less than 90 degrees. On this basis, as shown in FIG. 4, in this implementation, the electrode structure 02 includes the following.

1. The electrode structure 02 includes a first conductive pattern 022a, a first passivation layer 023a, a second conductive pattern 022b, and a second passivation layer 023b which are sequentially laminated along the direction away from the substrate 01. The orthographic projection of the first conductive pattern 022a on the substrate 01 is within the orthographic projection of the second conductive pattern 022b on the substrate 01. The electrode structure 02 includes two layers of conductive patterns 022 and two passivation layers 023.

In some embodiments, the thickness of the first conductive pattern 022a generally ranges from 1.8 μm to 2.8 μm, e.g., 2 μm; the thickness of the first passivation layer 023a and the thickness of the second passivation layer 023b generally range from 2000 angstroms (Å) to 4000 Å, e.g., 2000 Å; and the thickness of the second conductive pattern 022b generally ranges from 0.6 μm to 0.9 μm, e.g., 0.9 μm. It should be noted that the thickness direction in the embodiments of the present disclosure is a direction perpendicular to the bearing surface of the substrate 01.

2. The electrode structure 02 further includes a through hole K1 penetrating through the second passivation layer 023b and exposing the second conductive pattern 022b.

3. The electrode structure 02 further includes a protective layer 024 disposed in the through hole K1 and covering the second conductive pattern 022b. The protective layer 024 is used for protecting the exposed second conductive pattern 022b to prevent the second conductive pattern 022b from being corroded by water vapor in air.

4. The electrode structure 02 further includes a connection hole K2 penetrating through the first passivation layer 023a and exposing the first conductive pattern 022a. The second conductive pattern 022b is connected to the first conductive pattern 022a through the connection hole K2. The first conductive pattern 022a and the second conductive pattern 022b which are connected to each other are also referred to as connection portions included in the electrode structure 02.

It should be noted that the connection hole K2 is farther from at least one side surface C than the through hole K1 is, that is, as shown in FIG. 4, the through hole K1 is closer to the at least one side surface C. In addition, the orthographic projection of the through hole K1 on the substrate 01 and the orthographic projection of the first conductive pattern 022a on the substrate 01 do not overlap and are spaced apart from each other.

On the basis of FIG. 4, it can be seen in conjunction with the film layer structure diagram shown in FIG. 5 that the electrode structure 02 disposed in the peripheral region A2 now generally includes a buffer layer 021, a first conductive pattern 022a, a first passivation layer 023a, a second conductive pattern 022b, and a second passivation layer 023b which are sequentially laminated along the direction away from the substrate 01. That is, the first passivation layer 023a is directly lapped on the side of the first conductive pattern 022a away from the substrate 01. The first passivation layer 023a and the second conductive pattern 022b climb up the first conductive pattern 022a at the connection hole K2 in the connection portion. Since the first passivation layer 023a and the second conductive pattern 022b are relatively thin (e.g., 0.4 μm and 0.9 μm, respectively), and the first conductive pattern 022a is relatively thick (e.g., 2 μm), the spreadability of the first passivation layer 023a and the second conductive pattern 022b is not good at the climbing position of the first conductive pattern 022, which may lead to peeling between the film layers or even fracture of the film layers when the problem is serious.

In the embodiments of the present disclosure, still referring to the film layer structure shown in FIG. 4, it can be seen that, in the display panel provided in the embodiments of the present disclosure, in addition to the above film layers, the electrode structure 02 further includes the following.

5. The electrode structure 02 further includes a spacer layer 025 disposed between the first conductive pattern 022a and the first passivation layer 023a.

The orthographic projection of the spacer layer 025 on the substrate 01 is within the orthographic projection of the first passivation layer 023a on the substrate 01, and the spacer layer 025 covers the side surface C of the first conductive pattern 022a which is in contact with the buffer layer 021 and the top surface of the first conductive pattern 022a which is away from the buffer layer 021. The thickness of the spacer layer 025 is greater than the thickness of any one of the other film layers in the electrode structure 02. Exemplarily, the thickness of the spacer layer 025 is greater than 3 μm. For example, in some embodiments, the thickness of the spacer layer 025 is 4 μm.

That is, in the embodiments of the present disclosure, the spacer layer 025 is provided to wrap the edges of the first conductive pattern 022a, such that the segment different of the second conductive pattern 022b is formed by means of the spacer layer 025 instead of being formed directly by means of the first passivation layer 023a. Since the spacer layer 025 is relatively thick, on the one hand, the spacer layer 025 can have better spreadability at the climbing position of the first conductive pattern 022a without the risk of film layer fracture, and on the other hand, the angle α3 between the spacer layer 025 and the bearing surface of the substrate 01 is smaller, that is, the climbing slope is gentler, which is more suitable for the coverage and wrapping of a thinner film layer. On this basis, the first angle α1 between any passivation layer 023 and the bearing surface of the substrate 01 is made less than the second angle α2 between the conductive pattern 022 close to the substrate 01 and the bearing surface of the substrate 01, which can avoid the first passivation layer 023a and the second conductive pattern 022b climbing the steep slope of the first conductive pattern 022a. That is, a gentler slope is formed by means of the thicker spacer layer 025, which helps improve the spreadability of the first passivation layer 023a and the second conductive pattern 022b, thereby preventing the defects of peeling of the first passivation layer 023a and the second conductive pattern 022b at the connection hole K2.

That is, in the embodiments of the present disclosure, the angle α3 between the spacer layer 025 and the bearing surface of the substrate 01 may also be less than the second angle α2. Additionally, in some embodiments, the first angle α1 between any passivation layer 023 and the bearing surface of the substrate 01 may also be equal to the angle α3. Moreover, the first angles α1 between the various passivation layers 023 and the bearing surface of the substrate 01 are equal, and the fourth angle (not marked in the figure) between the second conductive pattern 022b and the bearing surface of the substrate 01 may also be equal to the first angle α1. In this way, better coverage between adjacent film layers is further ensured, thereby avoiding the film layers from peeling.

In the embodiments of the present disclosure, the spacer layer 025 is made of a resin material which may be made to be relatively thick and to have a smooth surface. For the position where peeling easily occurs, please refer to region Q1 marked in FIG. 5. In region Q1, the first passivation layer 023a, the second conductive pattern 022b, the second passivation layer 023b and other film layers climb up the side edge of the first conductive pattern 022a at the boundary of the connection hole K2 through which the first conductive pattern 022a and the second conductive pattern 022b in the current display panel are connected. In the embodiments of the present disclosure, a thicker spacer layer 025 is provided between the first conductive pattern 022a and the first passivation layer 023a to better cover the side edge of the first conductive pattern 022a, such that the film layers such as the second conductive pattern 022b and the second passivation layer 023b can subsequently maintain better spreadability at the climbing position at the side edge of the spacer layer 025, thereby better solving the defects of peeling between film layers.

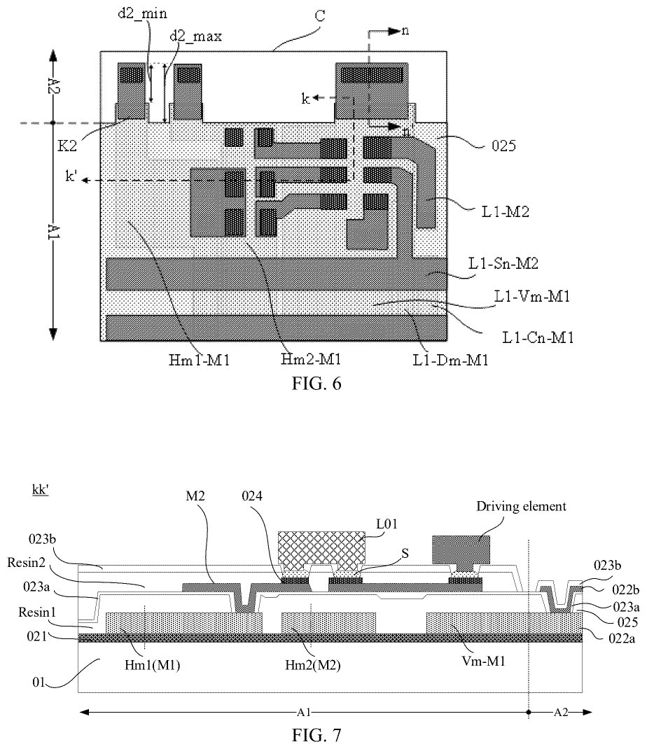

In some embodiments, FIG. 6 is a front diagram of a display panel, FIG. 4 is a sectional diagram of the structure shown in FIG. 6 along the nn′ direction, and FIG. 7 is a sectional diagram of the structure shown in FIG. 6 along the kk′ direction.

As can be seen from FIG. 6 and FIG. 7, the display region A1 of the front surface of the display panel provided in the embodiments of the present disclosure includes a buffer layer 021, a first wire layer M1, a first resin layer Resin1, a first passivation layer 023a, a second wire layer M2, a second resin layer Resin2, and a second passivation layer 023b which are sequentially laminated along the direction away from the substrate 01. The first wire layer M1 and the second wire layer M2 are used for forming a plurality of front surface wires L1.

Additionally, as can be further seen from FIG. 6, in the display panel provided in the embodiments of the present disclosure, the first resin layer Resin1 in the display region A1 extends to the peripheral region A2 to act as the spacer layer 025 of the electrode structure 02. That is, in the embodiments of the present disclosure, the resin layer is disposed not only in the display region A1 of the front surface but also in the peripheral region A2 of the front surface, and the orthographic projection of the resin layer on the substrate 01 overlaps the orthographic projection of the electrode structure 02 on the substrate 01. Furthermore, as shown in FIG. 4, the resin layer further covers the side edges of the first conductive pattern 022a and does not shield the connection hole K2. Therefore, the film layers such as the second conductive pattern 022b and the second passivation layer 023b can subsequently maintain better spreadability at the climbing position at the side edge of the spacer layer 025, thereby better solving the defects of peeling between film layers. In combination with FIG. 5, it can be seen that in the display panel in the related art, the first resin layer Resin1 is only disposed in the display region A1 of the front surface and does not extend to the peripheral region A2, i.e., in the related art, the orthographic projection of the first resin layer Resin1 on the substrate 01 does not overlap the orthographic projection of the first conductive pattern 022a on the substrate 01, and the resin layer is farther from the at least one side surface C than the electrode structure 02 is. Therefore, the peeling problem of the film layers described above is very likely to occur in the region Q1.

In some embodiments, as can be seen from FIG. 6, the minimum spacing d2_min between the side of the spacer layer 025 close to the at least one side surface C and the side of the electrode structure 02 close to the at least one side surface C is generally about 105 μm, and the maximum spacing d2_max between the side of the spacer layer 025 close to the at least one side surface C and the side of the electrode structure 02 close to the at least one side surface C is generally about 170 μm.

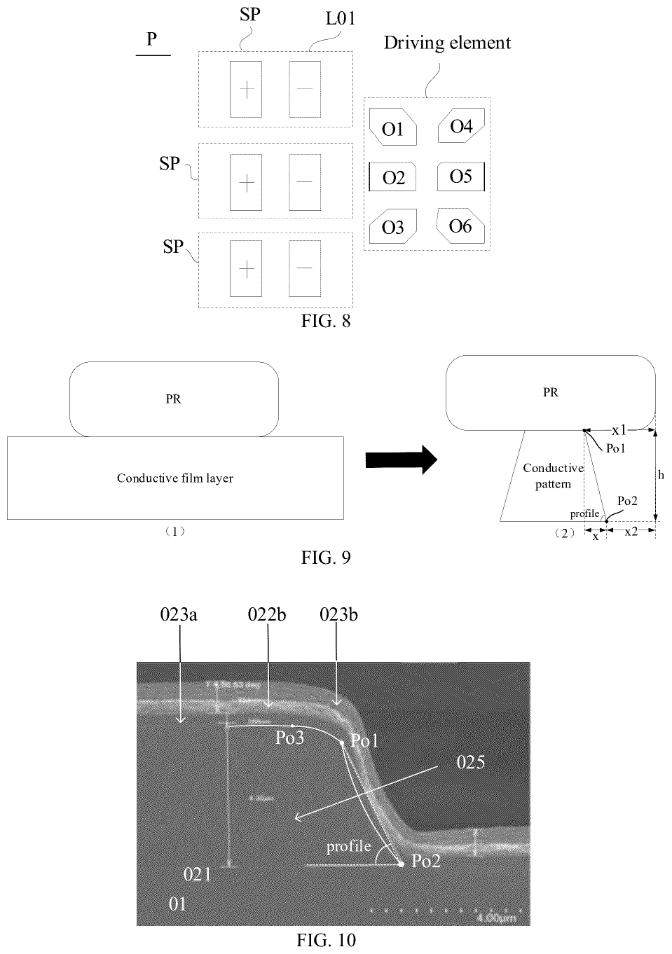

In some embodiments, on the basis of FIG. 6, it can be seen in conjunction with the local schematic diagrams of the display panels shown in FIG. 1 and FIG. 8 that the display panel provided in the embodiments of the present disclosure includes a plurality of pixels P arranged in an array as shown in FIG. 1, the plurality of pixels P are arranged in N rows and M columns, and each of the pixels P includes at least three different colors of sub-pixels SP and a driving element that drives the sub-pixels SP to emit light. Each sub-pixel SP includes at least one light-emitting element L01. The light-emitting element L01 and the driving element are disposed on the side of the second passivation layer 023b away from the substrate 01, as shown in FIG. 7.

Exemplarily, as shown in FIG. 8, the embodiments of the present disclosure are described by way of example where each pixel P includes three sub-pixels SP, and each sub-pixel SP includes one light-emitting element L01. In the figure, the three light-emitting elements L01 are arranged in three rows, and the three rows of light-emitting elements L01 are sequentially a first color (e.g., red) light-emitting element L01, a second color (e.g., green) light-emitting element L01, and a third color (e.g., blue) light-emitting element L01 from top to bottom.

In some embodiments, the second wire layer M2 forms a plurality of connection pads (not shown in the figure), and the plurality of connection pads are electrically connected to the light-emitting elements L01 and the driving element. For example, the pins of the light-emitting element L01 and the pins of the driving element are electrically connected to the corresponding connection pads by a soldering material S (e.g., soldering tin, a tin-silver-copper alloy, or a tin-copper alloy, etc.). In addition, as shown in FIG. 7, the protective layer 024 described in the foregoing embodiments is further provided on the connection pads. The pins of the light-emitting element L01 are electrically connected to two connection pads through via holes penetrating through the second passivation layer 023b and the second resin layer Resin2, and the pins of the driving element are connected to six connection pads through via holes penetrating through the second passivation layer 023b and the second resin layer Resin2. In this way, the light-emitting element L01 emits light under the control of the signals transmitted by the signal line and under the control of the driving element.

In some embodiments, as can be further seen from FIG. 6 and FIG. 7, the front surface wires L1 formed by the first wire layer M1 include a data signal line Dm, a first positive signal line Hm1, a second positive signal line Hm2, a reference signal line Vm, and a scanning signal connection line Cn, and the front surface wires L1 formed of the second wire layer M2 include a plurality of scanning signal lines Sn. Each scanning signal line Sn is electrically connected to one scanning signal connection line Cn. The driving element is electrically connected to the negative electrode of the light-emitting element L01 driven by the driving element in each sub-pixel SP, at least one data signal line Dm of a plurality of data signal lines, at least one scanning signal line Sn of a plurality of scanning signal lines, and at least one reference signal line Vm of a plurality of reference signal lines. The driving element is configured to write, under the control of the scanning signal line Sn, the signal from the data signal line Dm into different colors of sub-pixels SP at different times. The reference signal line Vm is configured to provide a negative signal for the driving element to generate a current path between the driving element and the light-emitting element L01, that is, the light-emitting element L01 can reliably emit light under the driving of the signal transmitted by the front surface wire L1.

In some embodiments, as can be further seen from FIG. 8, the driving element has a first signal terminal O1, a second signal terminal O2, a third signal terminal O3, a fourth signal terminal O4, a fifth signal terminal O5, and a sixth signal terminal O6. The first signal terminal O1 is connected to the negative electrode of the first color light-emitting element L01, the second signal terminal O2 is connected to the negative electrode of the second color light-emitting element L01, the third signal terminal O3 is connected to the negative electrode of the third color light-emitting element L01, the fourth signal terminal O4 is electrically connected to the data signal line Dm, the fifth signal terminal O5 is connected to the scanning signal line Sn, and the sixth signal terminal O6 is connected to the reference signal line Vm. The positive electrode of the first color light-emitting element L01 is connected to the second positive signal line Hm2, the positive electrode of the second color light-emitting element L01 is connected to the first positive signal line Hm1, and the positive electrode of the third color light-emitting element L01 is connected to the first positive signal line Hm1. The scanning signal line Sn is connected to the scanning signal connection line Cn.

On the basis of the foregoing embodiments, FIG. 10 shows a microphotograph of a display panel where the spacer layer 025 is provided to cover the side edges of the first conductive pattern 022a. As can be seen from FIG. 10, for the solution shown in FIG. 5, the first passivation layer 023a has a larger angle at the climbing position of the first conductive pattern 022a, and the angle is generally 69.8 degrees on average and may even reach a maximum of 77.4 degrees. In the case that the solution shown in FIG. 4 in the embodiments of the present disclosure is adopted, the angle at the climbing position obviously becomes smaller, and can be reduced to about 35 degrees on average, and the maximum value is about 41.2 degrees, which is not too large. Therefore, the angle is reduced by about 35 degrees, and the slope can be reduced to half of the original, which ensures that the first passivation layer 023a can better cover a side of the first conductive pattern 022a.

By way of example where a conductive pattern (e.g., the first conductive pattern 022a disposed in the same layer as the first wire layer M1) has an angle profile, the definition of the angle profile of any film layer in the embodiments of the present disclosure is described as follows in conjunction with FIG. 9. In the manufacturing process, a conductive film layer is first formed on the substrate 01 as shown in step (1) in FIG. 9; next, patterned photoresist (PR) is provided on the side of the conductive film layer away from the substrate 01; and then processes of exposure, development, etching and the like are performed on the conductive film layer using the patterned PR to pattern the conductive film layer so as to acquire a desired conductive pattern. Because of the anisotropy of the etching process, a conductive pattern with an angle profile as shown in step (2) is finally formed. Exemplarily, as can be further seen from FIG. 9, the angle profile finally formed satisfies: tan (profile)=h/x, where x=x1−x2.

Here, X1 represents a lateral etching amount at point Po1 of the conductive pattern, which is also referred to as a top lateral etching amount, and the lateral etching amount is mainly related to the strength of the adhesive force between the conductive film layer and the PR. h represents a thickness of the conductive film layer, and is determined by the coating process. X2 represents a lateral etching amount at point Po2 of the conductive pattern, which belongs to a critical dimension basis (CD bias), and is related to an etching duration, a concentration of an etching solution, a material of the conductive film layer, and the strength of the adhesive force between the conductive film layer and the PR. It can be seen that the angle profile formed is related to the top lateral etching amount, the CD bias, and the thickness of the conductive film layer. Under the same etching conditions, the larger the thickness of the conductive film layer, the larger the angle profile of the formed conductive pattern; and conversely, the smaller the thickness of the conductive film layer, the smaller the angle profile of the formed conductive pattern. That is, the angle profile of the formed conductive pattern is positively correlated with the thickness of the conductive film layer. Under the premise that the thickness of the conductive film layer is fixed, the angle profile of the conductive pattern can be changed by adjusting the top lateral etching amount and the CD bias.

The measurement method of the angles in the embodiments of the present disclosure is described in connection with the microphotograph shown in FIG. 10 by taking the third angle α3 between the spacer layer 025 and the bearing surface of the substrate 01 as an example. As can be seen from the figure, instead of having a section with a straight-line segment on the side edge as the metal pattern shown in FIG. 9, the spacer layer 025 has a section with a curved segment on the side edge, and there is a corresponding tangent line at each point on the curved segment. Accordingly, the angle between each film layer and the bearing surface of the substrate 01 in the embodiments of the present disclosure refers to the angle profile between the line between the highest point Po1 and the lowest point Po2 of the curved segment and the bearing surface of the substrate 01. The highest point Po1 is not point Po3 on the curved segment which has the largest distance from the substrate 01 as shown in FIG. 10, but is a point where the slope of the tangent line suddenly changes (i.e., the point where the slope changes the most) among various points on the curved segment, for example, point Po1 shown in FIG. 10. Point Po1 may also be defined as the highest point at the side edge of the section of the spacer layer 025.

In some embodiments, FIG. 11 is a schematic structural diagram of film layers of another display panel. As can be seen from FIG. 11, the electrode structure 02 provided in the embodiments of the present disclosure further includes a third passivation layer 023c disposed between the first conductive pattern 022a and the spacer layer 025. The connection hole K2 penetrates through the third passivation layer 023c to expose the first conductive pattern 022a. On the basis that the spacer layer 025 is provided, the third passivation layer 023c is further provided between the spacer layer 025 and the first conductive pattern 022a, which can protect the first conductive pattern 022a.

It should be noted that the structure shown in FIG. 11 and the structure shown in FIG. 4 may be considered as two parallel implementations proposed on the basis of the optional implementation described above (that is, the first angle α1 and the second angle α2 are both greater than 0 degree and less than 90 degrees). That is, in some embodiments, as shown in FIG. 4, the electrode structure 02 includes a first conductive pattern 022a, a spacer layer 025, a first passivation layer 023a, a second conductive pattern 022b, and a second passivation layer 023b which are sequentially laminated. In some other embodiments, as shown in FIG. 11, the electrode structure 02 includes a first conductive pattern 022a, a third passivation layer 023c, a spacer layer 025, a first passivation layer 023a, second conductive pattern 022b, and a second passivation layer 023b which are sequentially laminated.

In an alternative optional implementation, the first angle α1 between any passivation layer 023 and the bearing surface of the substrate 01 is equal to the second angle 2 between the conductive pattern 022 close to the substrate 01 and the bearing surface of the substrate 01, and the first angle α1 and the second angle α2 are both 0 degree. That is, the any passivation layer 023 and the conductive pattern 022 close to the substrate 01 are both parallel to the substrate 01. On this basis, as shown in FIG. 12, the electrode structure 02 in this implementation includes the following.

1. The electrode structure 02 includes a first conductive pattern 022a, a first passivation layer 023a, and a second passivation layer 023b which are sequentially laminated along the direction away from the substrate 01. That is, the electrode structure 02 includes one layer of conductive pattern 022 and two passivation layers 023.

2. The electrode structure 02 further includes a through hole K1 penetrating through the first passivation layer 023a and the second passivation layer 023b and exposing the first conductive pattern 022a. As described in the foregoing embodiments, the through hole K1 is close to the at least one side surface C. Generally, the distance between the side edge of the through hole K1 close to the at least one side surface and the boundary of the at least one side surface is about 11 μm.

3. The electrode structure 02 further includes a protective layer 024 disposed in the through hole K1 and covering the first conductive pattern 022a.

In this alternative optional implementation, it may be considered that the second conductive pattern 022b provided in the foregoing embodiments is removed and one layer of the first conductive pattern 022a is directly used as a bonding terminal to be electrically connected to the side wire L2. Comparing FIG. 3 and FIG. 11, it can be seen that, compared to the optional implementation described above, there is no need to form the connection hole for connecting the first conductive pattern 022a and the second conductive pattern 022b in this alternative optional implementation, i.e., there is no need to provide the connection portion, and accordingly, there is no structure that the second conductive pattern 022b climbs up the side surface of the first conductive pattern 022a described in the foregoing embodiments. Therefore, the problem of peeling between the film layers due to the slope-climbing is essentially solved.

In some embodiments, as can be seen from FIG. 6 and FIG. 7, the first surface wires L1 in the embodiments of the present disclosure include the first wire layer M1 and the second wire layer M2 which are sequentially laminated along the direction away from the substrate 01.

On this basis, as can be seen from the film layer structure diagram shown in FIG. 4, in the optional implementation described above, in the two layers of conductive patterns 022 sequentially laminated, i.e., the first conductive patterns 022a and the second conductive patterns 022b, included in the electrode structure 02 provided in the embodiments of the present disclosure, the first conductive pattern 022a is disposed in the same layer as the first wire layer M1, and the second conductive pattern 022b is disposed in the same layer as the second wire layer M2. As can be seen from the film layer structure diagram shown in FIG. 11, in the alternative optional implementation described above, the layer of the first conductive pattern 022a included in the electrode structure 02 provided in the embodiments of the present disclosure is disposed in the same layer as the first wire layer M1.

It should be noted that layers disposed in the same layer refer to a layer structure formed by forming film layers for forming a specific pattern using the same film forming process and then patterning the film layers by a single patterning process using the same mask. Based on different specific patterns, the single patterning process includes multiple exposures, developments or etching processes, and the specific pattern in the formed layer structure is continuous or discontinuous. That is, the plurality of elements, components, structures, and/or portions disposed in the “same layer” are made of the same material and formed by the same patterning process. In this way, the manufacturing processes can be simplified, the manufacturing cost can be saved, and the manufacturing efficiency can be increased.

It should also be noted that, as described in the foregoing embodiments, the thickness of the first wire layer M1 is generally greater than the thickness of the second wire layer M2. Therefore, compared to the optional implementation that the electrode structure 02 includes the first conductive pattern 022a and the second conductive pattern 022b which are respectively disposed in the same layer as the first wire layer M1 and the second wire layer M2, in the alternative optional implementation that the electrode structure 02 only includes the first conductive pattern 022a disposed in the same layer as the first wire layer M1, the overall thickness of the film layers of the electrode structure 02 close to the at least one side surface C is larger, and is generally about 1.1 μm. For example, in the optional implementation described above, the electrode structure 02 close to the at least one side surface C mainly includes the buffer layer 021, the first passivation layer 023a, the second conductive pattern 022b (i.e., the second wire layer M2), and the second passivation layer 023b. In the alternative optional implementation described above, the electrode structure 02 close to the at least one side surface C mainly includes the buffer layer 021, the first passivation layer 023a, the first conductive pattern 022a (i.e., the first wire layer M1), and the second passivation layer 023b, and further includes another buffer layer on the side of the second passivation layer 023b close to the substrate 01. The larger the thickness, the more unfavorable to the subsequent edge grinding process.

In some embodiments, as can be further seen from FIG. 4, FIG. 11, and FIG. 12, in the electrode structure 02 provided in the embodiments of the present disclosure, the thickness of the protective layer 024 is greater than the depth of the through hole K1 in which the protective layer 024 is disposed. For example, the thickness of the protective layer 024 is about 3 μm to 4 μm.

In some embodiments, the material of the protective layer 024 includes a metal material. For example, the material of the protective layer 024 includes nickel and/or gold.

It should be noted that the improvement way of the peeling problem provided in the foregoing embodiments may be considered as an improvement way from the perspective of a design end, and another improvement way from the perspective of the process end is described in the following embodiments.

Firstly, in the embodiments of the present disclosure, the film layer structure of at least one layer of conductive pattern 022 in the electrode structure 02 is improved to slow down the slope so as to increase the coverage effect of the film layer and improve the peeling problem of the film layer.

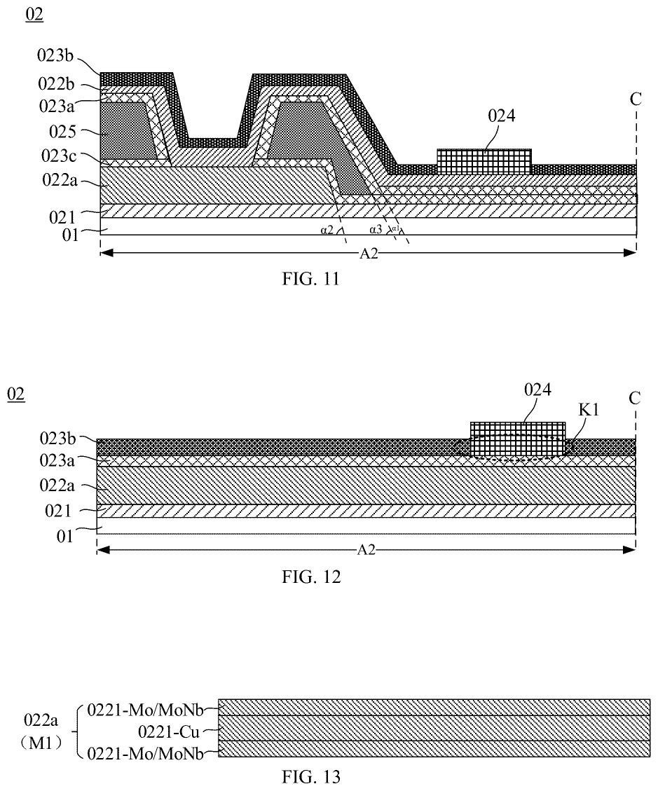

In some embodiments, as shown in FIG. 13, in the electrode structure 02 provided in the embodiments of the present disclosure, the at least one layer of conductive pattern 022 includes a plurality of layers of sub-conductive patterns 0221 which are sequentially laminated along the direction away from the substrate 01.

Exemplarily, in the electrode structure 02 shown in FIG. 13, the at least one layer of conductive pattern 022 includes three layers of sub-conductive patterns 0221 which are sequentially laminated along the direction away from the substrate 01. Furthermore, in the embodiments of the present disclosure, the materials of the three layers of sub-conductive patterns 0221 sequentially include molybdenum Mo, copper Cu, and molybdenum Mo, i.e., a Mo/Cu/Mo structure. Alternatively, the materials of the three layers of sub-conductive patterns 0221 sequentially include molybdenum and niobium MoNb, copper Cu, and molybdenum and niobium MoNb, i.e., a MoNb/Cu/MoNb structure. In some embodiments, the thicknesses of the layers in the Mo/Cu/Mo structure are sequentially 150 Å, 9000 Å, and 800 Å, and the thicknesses of the layers in the MoNb/Cu/MoNb structure are sequentially 150 Å, 20000 Å, and 150 Å. Here, the thicknesses and the materials are merely exemplary.

In the embodiments of the present disclosure, the at least one layer of conductive pattern 022 includes a conductive pattern 022, close to a side of the substrate 01, of the at least one layer of conductive pattern 022 included in the electrode structure 02, e.g., the first conductive pattern 022a (i.e., the first wire layer M1) described in the foregoing embodiments. In some other embodiments, the at least one layer of conductive pattern 022 includes a conductive pattern 022, away from the side of the substrate 01, of the at least one layer of conductive pattern 022 included in the electrode structure 02, e.g., the second conductive pattern 022b described in the foregoing embodiments. Accordingly, in the embodiments of the present disclosure, the first conductive pattern 022a is also referred to as a Cu1 layer, and the second conductive pattern 022b is also referred to as a Cu2 layer.

It should be noted that in the current display panel, the structure of the first wire layer M1 generally at most includes molybdenum Mo and copper Cu sequentially laminated along the direction away from the substrate 01. As can be seen from FIG. 5, the first passivation layer 023a is directly provided on a side of the first conductive pattern 022a which is disposed in the same layer as the first wire layer M1, and due to the influence of the material, the first passivation layer 023a and copper Cu have a weaker adhesive force therebetween and are prone to peeling. In the embodiments of the present disclosure, the structure of the first wire layer M1 is improved to include molybdenum Mo, copper Cu and molybdenum Mo or molybdenum and niobium MoNb, copper Cu, and molybdenum and niobium MoNb sequentially laminated along the direction away from the substrate 01, which can directly reduce the angle between the first conductive pattern 022a which is disposed in the same layer as the first wire layer M1 and the bearing surface of the substrate 01, and slow down the slope of the first conductive pattern 022a, thereby facilitating the coverage of the film layers disposed on the side of the first conductive pattern 022a away from the substrate 01, ensuring the coverage completeness of the first passivation layer 023a at the climbing position of the first conductive pattern 022a, and improving the peeling problem of the film layers.

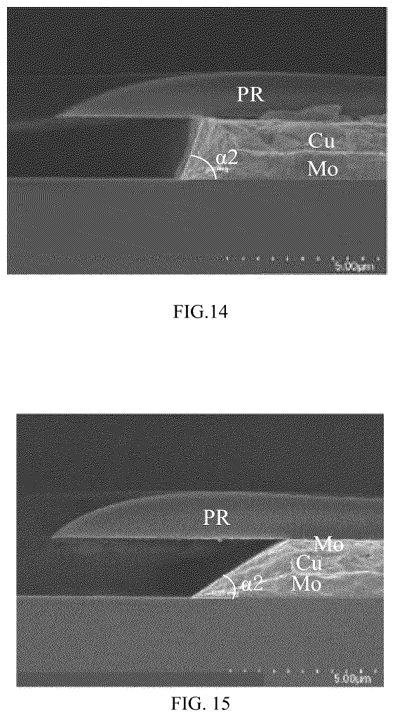

Exemplarily, on the basis of the structure that the first wire layer M1 (i.e., the first conductive pattern 022a) includes molybdenum Mo and copper Cu which are sequentially laminated, FIG. 14 is a schematic of an SEM slice by way of example where the thicknesses of the film layers of the Mo/Cu structure are respectively 300 Å and 20000 Å. On the basis that the first wire layer M1 includes molybdenum Mo, copper Cu and molybdenum Mo which are sequentially laminated, FIG. 15 shows another microphotograph by way of example where the thicknesses of the film layers of the Mo/Cu/Mo structure are respectively 300 Å, 20000 Å, and 17 Å. Comparing FIG. 14 and FIG. 15, it can be seen that the angle α2 between the current first conductive pattern 022a including only the Mo/Cu structure and the bearing surface of the substrate 01 is about 71 degrees, and the angle α2 between the first conductive pattern 022a including the Mo/Cu/Mo structure and the bearing surface of the substrate 01 in the embodiments of the present disclosure is reduced to 32.6 degrees. The angles are merely exemplary herein. In addition, FIGS. 14 and 15 further show the PR provided on one side of the first conductive pattern 022a.

In some embodiments, the materials and thicknesses of the other film layers are described as follows. The materials of the buffer layer 021 and the passivation layer 022 both include silicon nitride SiNx and/or silicon oxide SiOx, and the thickness of the buffer layer 021 is about 1000 Å to 2000 Å, for example, generally 1500 Å.

Secondly, in the embodiments of the present disclosure, the at least one passivation layer 023 in the electrode structure 02 is set to have a larger thickness to increase the spreadability of the passivation layer 023, thereby improving the subsequent peeling problem of film layers due to the segment difference in the first conductive pattern 022a.

In some embodiments, the thickness of the at least one passivation layer 023 in the electrode structure 02 is greater than 2000 Å and less than or equal to 4000 Å. For example, the thickness of the at least one passivation layer 023 is 4000 Å.

In some embodiments, the at least one passivation layer 023 with a larger thickness includes a passivation layer 023, away from on a side of the substrate 01, of the at least one passivation layer 023, e.g., the second passivation layer 023b described in the foregoing embodiments. In some other embodiments, the at least one passivation layer 023 with a larger thickness includes a passivation layer 023 close to the side of the substrate 01, e.g., the first passivation layer 023a described in the foregoing embodiments. In this way, the spreadability of the film layers can also be improved, thereby improving the peeling problem of the film layers.

It can be seen from the foregoing embodiments that, in one aspect, the spacer layer is added or the connection hole is not formed from the perspective of the design end to improve the peeling problem of the film layers, and in another aspect, the structure of the film layer is improved and/or the thickness of the film layer is adjusted from the perspective of the process end to improve the peeling problem of the film layers. Finally, a good yield of the product can be ensured.

In summary, the embodiments of the present disclosure provide a display panel. In the display panel, the side wire is electrically connected to the first surface wire through an electrode structure and extends through the first surface and the side surface in sequence to the second surface. The electrode structure includes at least one layer of conductive pattern and at least one passivation layer disposed on a side, away from the substate, of each layer of conductive pattern, which are sequentially laminated along the direction away from the substrate. The angle between any passivation layer and the bearing surface of the substrate is less than or equal to the second angle between the conductive pattern close to the substrate and the bearing surface of the substrate, which can prevent the angle from being too large due to the influence of the manufacturing process, thereby preventing the film layers from climbing and peeling. Therefore, a better yield of the product can be ensured.

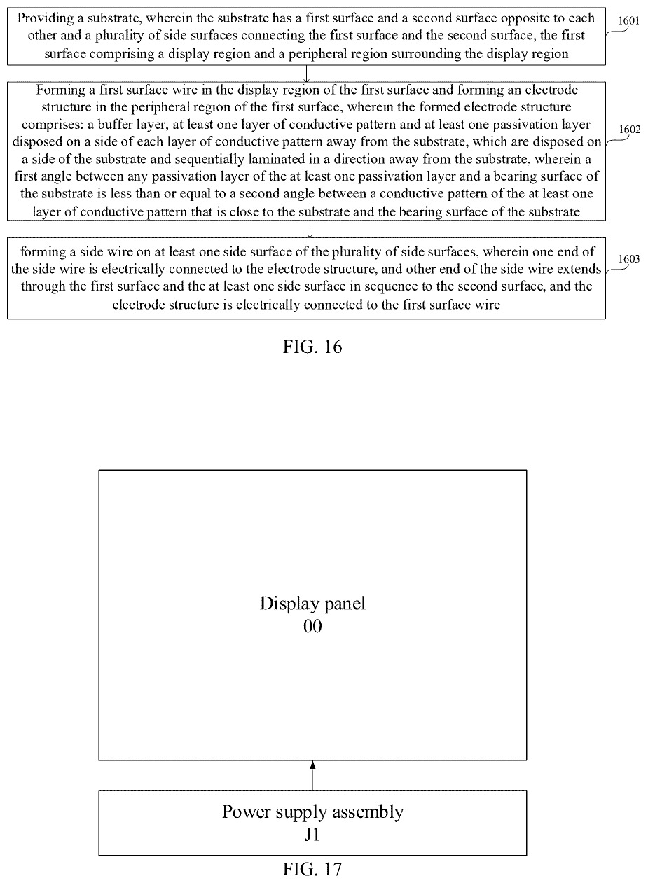

FIG. 16 is a flowchart of a method of manufacturing a display panel according to some embodiments of the present disclosure. This method is applicable to manufacturing the display panel described in the foregoing embodiments. As shown in FIG. 16, the method includes the following steps.

In step 1601, a substrate is provided, and the substrate has a first surface and a second surface opposite to each other and a plurality of side surfaces connecting the first surface and the second surface. The first surface includes a display region and a peripheral region surrounding the display region.

In step 1602, a first surface wire is formed in the display region of the first surface, and an electrode structure is formed in the peripheral region of the first surface. The formed electrode structure includes a buffer layer, at least one layer of conductive pattern, and at least one passivation layer disposed on the side, away from the substrate, of each layer of conductive pattern, which are disposed on a side of the substrate and sequentially laminated along the direction away from the substrate. A first angle between any passivation layer of the at least one passivation layer and a bearing surface of the substrate is less than or equal to a second angle between the conductive pattern of the at least one layer of conductive pattern which is close to the substrate and the bearing surface of the substrate.

In step 1603, a side wire is formed on at least one side surface of the plurality of side surfaces. One end of the side wire is electrically connected to the electrode structure, and the other end of the side wire extends through the first surface and the at least one side surface in sequence to the second surface, and the electrode structure is electrically connected to the first surface wire.

In an optional implementation, as shown in FIG. 4, in the formed electrode structure 02, the first angle α1 is less than the second angle α2, and the first angle α1 and the second angle α2 are both greater than 0 degree and less than 90 degrees. In this implementation, the above step 1602 of forming the electrode structure in the peripheral region of the first surface includes the following steps.

In α1, a first conductive pattern, a first passivation layer, a second conductive pattern, and a second passivation layer which are sequentially laminated along the direction away from the substrate are formed on a side of the substrate. The orthographic projection of the first conductive pattern on the substrate is within the orthographic projection of the second conductive pattern on the substrate.

In b1, a through hole penetrating through the second passivation layer and exposing the second conductive pattern is formed.

In c1, a protective layer covering the second conductive pattern is formed in the through hole.

In d1, a connection hole penetrating through the first passivation layer and exposing the first conductive pattern is formed, and the formed connection hole is farther from the at least one side surface than the through hole is.

In e1, the second conductive pattern is connected to the first conductive pattern through the connection hole.

In f1, a spacer layer is formed between the first conductive pattern and the first passivation layer. The orthographic projection of the spacer layer on the substrate is within the orthographic projection of the first passivation layer on the substrate, and the spacer layer covers the side surface of the first conductive pattern which is in contact with the buffer layer and the top surface of the first conductive pattern which is away from the buffer layer. The thickness of the spacer layer is greater than the thickness of any other film layer in the electrode structure.

In an alternative optional implementation, as shown in FIG. 12, in the formed electrode structure 02, the first angle α1 is equal to the second angle α2, and the first angle α1 and the second angle α2 are both 0 degree. In this implementation, the above step 1602 of forming the electrode structure in the peripheral region of the first surface includes the following steps.

In a2, a first conductive pattern, a first passivation layer, and a second passivation layer which are sequentially laminated along the direction away from the substrate are formed on a side of the substrate.

In b2, a through hole penetrating through the first passivation layer and the second passivation layer and exposing the first conductive pattern is formed.

In c2, a protective layer covering the first conductive pattern is formed in the through hole.

Optionally, as described in the foregoing embodiments, in the above step 1602, forming the first surface wire in the display region of the first surface includes: forming the first surface wire in the display region of the first surface by a yellow light process. Forming the side wire on at least one side surface of the plurality of side surfaces includes: forming the side wire on at least one side surface of the plurality of side surfaces by a laser etching process. Optionally, as described in the foregoing embodiments, in some embodiments, a second surface wire is also formed on the second surface to electrically connect the side wire and an external circuit board disposed on the second surface. Forming the second surface wire on the second surface includes: forming the second surface wire on the second surface by the yellow light process or the laser etching process.

The process of forming the front surface wire and the back surface wire by the yellow light process and simultaneously forming the side wire by the laser etching process is referred to as a double-sided BP process. The process of forming the front surface wire by the yellow light process and simultaneously forming the side wire and the back surface wire by the laser etching process is referred to as a single-sided BP process.

Optionally, the process of manufacturing the display panel is briefly described in the following embodiments by taking the film layer structure shown in FIG. 11, i.e., the above optional implementation, as an example.
1) A buffer layer 021 is manufactured on the provided substrate 01. In some embodiments, the substrate 01 is a glass substrate; and the buffer layer 021 is manufactured by a magnetron sputtering process, and the thickness of the buffer layer 021 is about 1500 Å.
2) Next, a Cu1 layer, i.e., a first conductive pattern 022a, is manufactured on the side of the buffer layer 021 away from the substrate 01. In some embodiments, the first conductive pattern 022a is manufactured by processes such as magnetron sputtering, cleaning, coating, baking, exposure, development, hard baking, etching, and lift-off, and the thickness of the first conductive pattern 022a is about 2 μm.
3) Next, a third passivation layer 023c is manufactured on the side of the Cu1 layer away from the substrate 01. In some embodiments, the third passivation layer 023c is manufactured by the magnetron sputtering process. Alternatively, in some embodiments, the third passivation layer 023c is manufactured by a chemical vapor deposition (CVD) process. The thickness of the third passivation layer 023c is about 2000 Å.
4) Next, a spacer layer 025 is manufactured on the side of the third passivation layer 023c away from the substrate 01. In some embodiments, the material of the spacer layer 025 includes a resin material, and the spacer layer 025 is manufactured by processes such as coating, exposure, and development, and the thickness of the spacer layer 025 is about 4 μm.
5) Next, a first passivation layer 023a is manufactured on the side of the spacer layer 025 away from the substrate 01. Similarly, the first passivation layer 023a is also manufactured by the magnetron sputtering process or the chemical vapor deposition process, and the thickness of the first passivation layer 023a is about 3000 Å. Thereafter, the first passivation layer 023a is etched by an etching process to form a connection hole K1 that exposes the first conductive pattern 022a.
6) Next, a Cu2 layer, i.e., a second conductive pattern 022b, is manufactured on the side of the first passivation layer 023a away from the substrate 01. Similarly, the second conductive pattern 022b is also manufactured by processes such as magnetron sputtering, cleaning, coating, baking, exposure, development, hard baking, etching, and lift-off. The thickness of the second conductive pattern 022b is about 0.9 μm.
(7) Next, a second passivation layer 023b is manufactured on the side of the second conductive pattern 022b away from the substrate 01. Similarly, the second passivation layer 023b is also manufactured by the magnetron sputtering process or the chemical vapor deposition process. It should be noted that, in some embodiments, the second passivation layer 023b includes two passivation sub-layers sequentially laminated along the direction away from the substrate 01, and may further include a resin layer disposed between the two passivation sub-layers. The thicknesses of the passivation sub-layers are 1500 Å and 4000 Å, respectively, and the thickness of the resin layer is about 2 μm. So far, the front surface process is completed.
8) The substrate is placed horizontally with the second surface facing upward, and at least a back surface wire and a wire protection layer are manufactured on the second surface. In some embodiments, the thickness of the back surface wire is about 9000 Å, and the thickness of the wire protection layer is about 520 Å. The material of the back surface wire includes copper Cu, and the material of the wire protection layer includes a transparent conductive material such as indium tin oxide (ITO). Finally, a passivation protection layer having a thickness of about 6000 Å is manufactured on the wire protection layer by the magnetron sputtering process or the chemical vapor deposition process, and the passivation protection layer is patterned to expose a portion of the surface of a laminated structure formed of the back surface wire and/or the wire protection layer. So far, the back surface process is completed. After the back surface process is completed, the substrate is turned upside down for the second time to place substrate horizontally with the first surface facing upward. The second passivation layer 023b is etched by a dry etching process to expose a portion of the surface of the electrode structure, and a protective layer 024 is provided on the exposed surface.
(9) A side wire is manufactured to connect the electrode structure and the corresponding back surface wire.

It should be noted that the process flows above are merely exemplary and do not limit the structure of the display panel provided in the embodiments of the present disclosure.

In summary, the embodiments of the present disclosure provide a method for manufacturing a display panel. In the display panel manufactured by this method, the side wire is electrically connected to the first surface wire through an electrode structure and extends through the first surface and the side surface in sequence to the second surface. The electrode structure includes at least one layer of conductive pattern and at least one passivation layer disposed on a side, away from the substate, of each layer of conductive pattern, which are sequentially laminated along the direction away from the substrate. The angle between any passivation layer and the bearing surface of the substrate is less than or equal to the second angle between the conductive pattern close to the substrate and the bearing surface of the substrate, which can prevent the angle from being too large due to the influence of the manufacturing process, thereby preventing the film layers from climbing and peeling. Therefore, a better yield of the product can be ensured.

FIG. 17 is a schematic structural diagram of a display device according to some embodiments of the present disclosure. As shown in FIG. 17, the display device includes a power supply assembly J1 and the display panel 00 as described in the foregoing embodiments.

The power supply assembly J1 is coupled to the display panel 00 and is configured to supply power to the display panel 00.

In some embodiments, the display device may be any product or component having a display function, such as a mini LED display device, an OLED display device, and a micro LED display device.

The terms used in the embodiments of the present disclosure are used for the purpose of explaining the embodiments of the present disclosure only and are not intended to limit the present disclosure. Unless otherwise defined, the technical or scientific terms used in the embodiments of the present disclosure should have the ordinary meaning as understood by a person of ordinary skill in the art to which the present disclosure belongs.

For example, the words “first”, “second”, “third” and the like used in the specification and claims of the present disclosure do not indicate any order, quantity, or importance, but rather are used to distinguish between different components.

Similarly, the words “a/an”, “one” and the like do not indicate a limitation in quantity, but rather indicate the existence of at least one.

The words “include”, “comprise” and the like mean that the element or object preceding “include” or “comprise” encompasses the elements, objects, or equivalents thereof listed after “include” or “comprise”, without excluding other elements or objects.

The words “on”, “under”, “left”, “right” and the like are used indicate the relative positional relationship only. When the absolute position of the described object is changed, the relative positional relationship may be changed accordingly.

The expression “and/or” indicates three kinds of relationships. For example, A and/or B means three circumstances, i.e., A exits alone, A and B exit concurrently, and B exits alone. The character “/” generally indicates an “or” relationship between the objects associated before and after.

Described above are optional embodiments of the present disclosure and are not intended to limit the present disclosure. Within the spirit and principles of the present disclosure, any variations, equivalent substitutions and improvements shall be included in the protection scope of the present disclosure.

1. A display panel, comprising:
a substrate having a first surface and a second surface opposite to each other and a plurality of side surfaces connecting the first surface and the second surface, wherein the first surface comprises a display region and a peripheral region surrounding the display region; and
a first surface wire disposed in the display region of the first surface, an electrode structure disposed in the peripheral region of the first surface, and a side wire disposed on at least one side surface of the plurality of side surfaces;
wherein one end of the side wire is electrically connected to the electrode structure, and another end of the side wire extends through the first surface and the at least one side surface in sequence to the second surface, and the electrode structure is further electrically connected to the first surface wire; and
the electrode structure comprises: a buffer layer, at least one layer of conductive pattern, and at least one passivation layer disposed on a side, away from the substrate, of each layer of conductive pattern, which are disposed on a side of the substrate and sequentially laminated along a direction away from the substrate, wherein a first angle between any passivation layer of the at least one passivation layer and a bearing surface of the substrate is less than or equal to a second angle between a conductive pattern of the at least one layer of conductive pattern which is close to the substrate and the bearing surface of the substrate.

2. The display panel according to claim 1, wherein the first angle and the second angle are equal and are both 0 degree; and the electrode structure comprises:
a first conductive pattern, a first passivation layer, and a second passivation layer which are sequentially laminated along the direction away from the substrate;
a through hole penetrating through the first passivation layer and the second passivation layer and exposing the first conductive pattern; and
a protective layer disposed in the through hole and covering the first conductive pattern.

3. The display panel according to claim 1, wherein the first angle is less than the second angle, and the first angle and the second angle are both greater than 0 degree and less than 90 degrees; and the electrode structure comprises:
a first conductive pattern, a first passivation layer, a second conductive pattern, and a second passivation layer which are sequentially laminated along the direction away from the substrate, wherein an orthographic projection of the first conductive pattern on the substrate is within an orthographic projection of the second conductive pattern on the substrate;
a through hole penetrating through the second passivation layer and exposing the second conductive pattern;
a protective layer disposed in the through hole and covering the second conductive pattern;
a connection hole penetrating through the first passivation layer and exposing the first conductive pattern, wherein the second conductive pattern is connected to the first conductive pattern through the connection hole, and the connection hole is farther from the at least one side surface than the through hole is; and
a spacer layer disposed between the first conductive pattern and the first passivation layer, wherein an orthographic projection of the spacer layer on the substrate is within an orthographic projection of the first passivation layer on the substrate, the spacer layer covers a side surface of the first conductive pattern which is in contact with the buffer layer and a top surface of the first conductive pattern which is away from the buffer layer, and a thickness of the spacer layer is greater than a thickness of any other film layer in the electrode structure.

4. The display panel according to claim 3, wherein
a third angle between the spacer layer and the bearing surface of the substrate is less than the second angle and is equal to the first angle; and
first angles between various passivation layers and the bearing surface of the substrate are equal, and a fourth angle between the second conductive pattern and the bearing surface of the substrate is equal to the first angle.

5. The display panel according to claim 3, wherein the thickness of the spacer layer is greater than 3 μm.

6. The display panel according to claim 3, wherein a material of the spacer layer includes a resin material.

7. The display panel according to claim 3, wherein the electrode structure further comprises:
a third passivation layer disposed between the first conductive pattern and the spacer layer, wherein the connection hole further penetrates through the third passivation layer to expose the first conductive pattern.

8. The display panel according to claim 2, wherein the first surface wire comprises: a first wire layer and a second wire layer which are sequentially laminated along the direction away from the substrate; wherein
one layer of first conductive pattern in the electrode structure is disposed in a same layer as the first wire layer; or
in two layers of conductive patterns comprising the first conductive pattern and a second conductive pattern which are sequentially laminated in the electrode structure, the first conductive pattern is disposed in a same layer as the first wire layer, and the second conductive pattern is disposed in a same layer as the second wire layer.

9. The display panel according to claim 2, wherein a thickness of the protective layer in the electrode structure is greater than a depth of the through hole, and a material of the protective layer comprises a metal material.

10. The display panel according to claim 9, wherein the material of the protective layer comprises: nickel, gold, or a combination thereof.

11. The display panel according to claim 1, wherein the at least one layer of conductive pattern in the electrode structure comprises: a plurality of layers of sub-conductive patterns which are sequentially laminated along the direction away from the substrate.

12. The display panel according to claim 11, wherein the at least one layer of conductive pattern in the electrode structure comprises: three layers of sub-conductive patterns which are sequentially laminated along the direction away from the substrate; wherein
materials of the three layers of sub-conductive patterns sequentially comprise molybdenum, copper, and molybdenum, or sequentially comprise molybdenum and niobium, copper, and molybdenum and niobium.

13. The display panel according to claim 11, wherein the at least one layer of conductive pattern comprises: a conductive pattern, close to the side of the substrate, of the at least one layer of conductive pattern.

14. The display panel according to claim 1, wherein a thickness of at least one passivation layer in the electrode structure is greater than 2000 Å and less than or equal to 4000 Å.

15. The display panel according to claim 14, wherein the at least one passivation layer comprises a passivation layer, away from the side of the substrate, of the at least one passivation layer.

16. A method for manufacturing a display panel, applicable for manufacturing the display panel according to claim 1; the method comprising:
providing a substrate, wherein the substrate has a first surface and a second surface opposite to each other and a plurality of side surfaces connecting the first surface and the second surface, the first surface comprising a display region and a peripheral region surrounding the display region;
forming a first surface wire in the display region of the first surface, and forming an electrode structure in the peripheral region of the first surface, wherein the electrode structure is electrically connected to the first surface wire; and
forming a side wire on at least one side surface of the plurality of side surfaces, wherein one end of the side wire is electrically connected to the electrode structure, and another end of the side wire extends through the first surface and the at least one side surface in sequence to the second surface;
wherein the formed electrode structure comprises: a buffer layer, at least one layer of conductive pattern, and at least one passivation layer disposed on a side, away from the substrate, of each layer of conductive pattern, which are disposed on a side of the substrate and sequentially laminated along a direction away from the substrate, wherein a first angle between any passivation layer of the at least one passivation layer and a bearing surface of the substrate is less than or equal to a second angle between a conductive pattern of the at least one layer of conductive pattern which is close to the substrate and the bearing surface of the substrate.

17. The method according to claim 16, wherein the first angle and the second angle are equal and are both 0 degree; and forming the electrode structure in the peripheral region of the first surface comprises:
forming a first conductive pattern, a first passivation layer, and a second passivation layer which are sequentially laminated along the direction away from the substrate on the side of the substrate;
forming a through hole penetrating through the first passivation layer and the second passivation layer and exposing the first conductive pattern; and
forming a protective layer covering the first conductive pattern in the through hole.

18. The method according to claim 16, wherein the first angle is less than the second angle, and the first angle and the second angle are both greater than 0 degree and less than 90 degrees; and forming the electrode structure in the peripheral region of the first surface comprises:
forming a first conductive pattern, a first passivation layer, a second conductive pattern, and a second passivation layer which are sequentially laminated along the direction away from the substrate on the side of the substrate, wherein an orthographic projection of the first conductive pattern on the substrate is within an orthographic projection of the second conductive pattern on the substrate;
forming a through hole penetrating through the second passivation layer and exposing the second conductive pattern;
forming a protective layer covering the second conductive pattern in the through hole;
forming a connection hole penetrating through the first passivation layer and exposing the first conductive pattern, wherein the connection hole is farther from the at least one side surface than the through hole is;
connecting the second conductive pattern to the first conductive pattern through the connection hole; and
forming a spacer layer between the first conductive pattern and the first passivation layer, wherein an orthographic projection of the spacer layer on the substrate is within an orthographic projection of the first passivation layer on the substrate, the spacer layer covers a side surface of the first conductive pattern which is in contact with the buffer layer and a top surface of the first conductive pattern which is away from the buffer layer, and a thickness of the spacer layer is greater than a thickness of any other film layer in the electrode structure.

19. A display device, comprising: a power supply assembly, and a display panel; wherein
the display panel comprises:
a substrate having a first surface and a second surface opposite to each other and a plurality of side surfaces connecting the first surface and the second surface, wherein the first surface comprises a display region and a peripheral region surrounding the display region; and
a first surface wire disposed in the display region of the first surface, an electrode structure disposed in the peripheral region of the first surface, and a side wire disposed on at least one side surface of the plurality of side surfaces;
wherein one end of the side wire is electrically connected to the electrode structure, and another end of the side wire extends through the first surface and the at least one side surface in sequence to the second surface, and the electrode structure is further electrically connected to the first surface wire; and
the electrode structure comprises: a buffer layer, at least one layer of conductive pattern, and at least one passivation layer disposed on a side, away from the substrate, of each layer of conductive pattern, which are disposed on a side of the substrate and sequentially laminated along a direction away from the substrate, wherein a first angle between any passivation layer of the at least one passivation layer and a bearing surface of the substrate is less than or equal to a second angle between a conductive pattern of the at least one layer of conductive pattern which is close to the substrate and the bearing surface of the substrate; and
the power supply assembly is coupled to the display panel and is configured to supply power to the display panel.

20. The display device according to claim 19, wherein the first angle and the second angle are equal and are both 0 degree; and the electrode structure comprises:
a first conductive pattern, a first passivation layer, and a second passivation layer which are sequentially laminated along the direction away from the substrate;
a through hole penetrating through the first passivation layer and the second passivation layer and exposing the first conductive pattern; and
a protective layer disposed in the through hole and covering the first conductive pattern.
